(19) United States
(12) Patent Application Publication
(10) Pub. No.: US 2025/0228018 A1
(43) Pub. Date: Jul. 10, 2025

(54) PHOTODETECTORS WITH INCREASED SENSITIVITY AND METHODS THEREOF

(71) Applicant: ActLight SA, Lausanne (CH)

(72) Inventors: Serguei OKHONIN, St-Sulpice (CH); Antoine LACROIX, Thonon-Les-Bains (FR); Maxim GUREEV, St-Sulpice (CH)

(73) Assignee: ActLight SA, Lausanne (CH)

(21) Appl. No.: 19/013,884

(22) Filed: Jan. 8, 2025

Related U.S. Application Data
(60) Provisional application No. 63/618,758, filed on Jan. 8, 2024.

(51) Int. Cl. H10F 30/26

(52) U.S. Cl. CPC H10F 30/263

(57) ABSTRACT

Techniques for increasing sensitivity of photodetectors are provided. The techniques utilize a photodetector including a top layer and/or a bottom layer comprising a central region and a side region. The central region(s) and the side region(s) are coupled to contacts that each receive and apply a respective voltage to adjust the sensitivity of the photodetector.

### CROSS-REFERENCE TO RELATED APPLICATIONS

This patent application claims priority to U.S. Provisional Patent Application No. 63/618,758, filed Jan. 8, 2024, which is hereby incorporated by reference herein in its entirety.

This patent application incorporates by reference U.S. Pat. No. 11,114,480 (the '480 patent), issued Sep. 7, 2021, entitled “Photodetector,” which issued from U.S. patent application Ser. No. 16/429,158, filed Jun. 3, 2019.

### FIELD OF THE DISCLOSURE

The present disclosure relates generally to photodetectors, and more particularly to improving photodetector sensitivity.

### BACKGROUND OF THE DISCLOSURE

A traditional photodetector operates by converting light incident on a surface of the photodetector to an electrical signal, from which useful information may be acquired. Fabrication of such photodetectors may include epitaxially adding various layers of semiconductor material at various doping concentrations over a substrate.

Once a photodetector is fabricated its sensitivity to incident light is limited at least in part by its structure. Thus, one approach to increasing the sensitivity of a photodetector is to increase the active area of the photodetector. However, this presents a problem in applications where space is limited. For example, some photodetectors may be optimized for a specific task depending on an expected amount of light intensity that will be encountered. Such a task may require more space than is available. Furthermore, increasing the size of a photodetector may lead to increased power requirements and/or manufacturing costs.

To cover a wide range of applications, multiple photodetectors may be used together in a single device. However, using multiple sensors may increase the amount of space required to house the sensors, the manufacturing cost, and/or the likelihood of failure due to increased complexity of circuitry and operation.

In view of the foregoing, it should be understood that there may be significant problems and shortcomings associated with current photodetector technologies.

### SUMMARY OF THE DISCLOSURE

Techniques for increasing the sensitivity of photodetectors are disclosed. In one particular embodiment, the techniques may be realized as a photodetector device comprising a top layer comprising a central region and a side region each composed of a first type of doped semiconductor material, the central region coupled to a first contact to receive a first voltage, the side region coupled to a second contact to receive a second voltage. The photodetector device also comprises a first light absorbing region composed of a second type of doped semiconductor material, a second light absorbing region composed of a third type of doped semiconductor material, and a bottom layer composed of a fourth type of doped semiconductor material and coupled to a third contact to receive a third voltage, where the first light absorbing region has a lower doping concentration than the bottom layer, and wherein the second light absorbing region has a lower doping concentration than the top layer.

In accordance with other aspects of this particular embodiment, the photodetector device further comprises a fourth contact coupled to the bottom layer to receive a fourth voltage.

In accordance with further aspects of this particular embodiment, the top layer comprises a dielectric formed between the central region of the top layer and the side region of the top layer.

In accordance with additional aspects of this particular embodiment the bottom layer comprises a central region coupled to the third contact and a side region coupled to a fourth contact to receive a fourth voltage, where the bottom layer is disposed adjacent the second light absorbing region.

In accordance with other aspects of this particular embodiment, the bottom layer further comprises a dielectric formed between the central region of the bottom layer and the side region of the bottom layer.

In accordance with further aspects of this particular embodiment the photodetector device operates at a first sensitivity responsive to the first voltage and the second voltage being the same and operates at a second sensitivity responsive to the second voltage being less than the first voltage, where the second sensitivity is higher than the first sensitivity.

In accordance with additional aspects of this particular embodiment, the second sensitivity increases as the second voltage decreases while the first voltage and the third voltage remain fixed.

In accordance with other aspects of this particular embodiment, the photodetector device operates at the first sensitivity responsive to setting the first voltage to 1 volt, the second voltage to 1 volt, and the third voltage to zero volts, wherein the photodetector device changes the second sensitivity by setting the second voltage to be less than the first voltage, or setting the third voltage to a nonzero voltage, where the photodetector device changes the second sensitivity by setting the second voltage to be less than the third voltage.

In accordance with other aspects of this particular embodiment, the first type of doped semiconductor material and the third type of doped semiconductor material may both be p-type doped semiconductor material, and the second type of doped semiconductor material and the fourth type of doped semiconductor material may both be n-type doped semiconductor material.

In accordance with other aspects of this particular embodiment, the first type of doped semiconductor material and the third type of doped semiconductor material may both be n-type doped semiconductor material, and the second type of doped semiconductor material and the fourth type of doped semiconductor material may both be p-type doped semiconductor material.

In another particular embodiment, the techniques may be realized as a method of increasing a sensitivity of a photodetector device, the method comprising providing the photodetector device with a top layer comprising a central region and a side region each composed of a first type of doped semiconductor material, the central region coupled to a first contact to receive a first voltage, the side region coupled to a second contact to receive a second voltage, a first light absorbing region composed of a second type of doped semiconductor material, a second light absorbing region composed of a third type of doped semiconductor material, and a bottom layer composed of a fourth type of doped semiconductor material and coupled to a third contact to receive a third voltage, where the first light absorbing region has a lower doping concentration than the bottom layer, and where the second light absorbing region has a lower doping concentration than the top layer. The method also comprises increasing the sensitivity of the photodetector device by setting the first contact to the first voltage, setting the third contact to the third voltage, and setting the second voltage to be less than the first voltage while the second voltage and the third voltage remain fixed.

In accordance with other aspects of this particular embodiment, providing the photodetector with the bottom layer comprises the bottom layer coupled to a fourth contact to receive a fourth voltage, where increasing the sensitivity of the photodetector device comprises setting the fourth contact to the fourth voltage.

In accordance with further aspects of this particular embodiment, providing the photodetector with the top layer comprises the top layer comprising a dielectric formed between the central region of the top layer and the side region of the top layer.

In accordance with additional aspects of this particular embodiment, providing the photodetector with the bottom layer comprises the bottom layer comprising a central region coupled to the third contact and a side region coupled to a fourth contact to receive a fourth voltage, where the bottom layer is disposed adjacent the second light absorbing region.

In accordance with other aspects of this particular embodiment, providing the photodetector with the bottom layer further comprises the bottom layer comprising a dielectric formed between the central region of the bottom layer and the side region of the bottom layer.

In accordance with further aspects of this particular embodiment, increasing the sensitivity of the photodetector device further comprises operating the photodetector device at a first sensitivity by setting the first voltage and the second voltage to be the same and operating the photodetector device at a second sensitivity by setting the second voltage to be less than the first voltage, where the second sensitivity is higher than the first sensitivity.

In accordance with additional aspects of this particular embodiment, the second sensitivity increases as the second voltage decreases while the first voltage and the third voltage remain fixed.

In accordance with other aspects of this particular embodiment, the first type of doped semiconductor material and the third type of doped semiconductor material may both be p-type doped semiconductor material, and the second type of doped semiconductor material and the fourth type of doped semiconductor material may both be n-type doped semiconductor material.

In accordance with other aspects of this particular embodiment, the first type of doped semiconductor material and the third type of doped semiconductor material may both be n-type doped semiconductor material, and the second type of doped semiconductor material and the fourth type of doped semiconductor material may both be p-type doped semiconductor material.

In another particular embodiment, the techniques may be realized as a method of manufacturing a photodetector device, the method comprising fabricating a top layer comprising a central region and a side region each composed of a first type of doped semiconductor material, the central region coupled to a first contact to receive a first voltage, the side region coupled to a second contact to receive a second voltage, fabricating a first light absorbing region composed of a second type of doped semiconductor material, fabricating a second light absorbing region composed of a third type of doped semiconductor material, and fabricating a bottom layer composed of a fourth type of doped semiconductor material and coupled to a third contact to receive a third voltage, where the first light absorbing region has a lower doping concentration than the bottom layer, and where the second light absorbing region has a lower doping concentration than the top layer.

In accordance with other aspects of this particular embodiment, fabricating the bottom layer comprises the bottom layer coupled to a fourth contact to receive a fourth voltage.

In accordance with additional aspects of this particular embodiment, fabricating the top layer comprises fabricating a dielectric between the central region of the top layer and the side region of the top layer.

In accordance with further aspects of this particular embodiment, fabricating the bottom layer comprises fabricating a central region in the bottom layer coupled to the third contact and fabricating a side region in the bottom layer coupled to a fourth contact to receive a fourth voltage, where the bottom layer is disposed adjacent the second light absorbing region.

In accordance with other aspects of this particular embodiment, fabricating the bottom layer further comprises forming a dielectric between the central region of the bottom layer and the side region of the bottom layer.

In accordance with other aspects of this particular embodiment, the first type of doped semiconductor material and the third type of doped semiconductor material may both be p-type doped semiconductor material, and the second type of doped semiconductor material and the fourth type of doped semiconductor material may both be n-type doped semiconductor material.

In accordance with other aspects of this particular embodiment, the first type of doped semiconductor material and the third type of doped semiconductor material may both be n-type doped semiconductor material, and the second type of doped semiconductor material and the fourth type of doped semiconductor material may both be p-type doped semiconductor material.

The present disclosure will now be described in more detail with reference to particular embodiments thereof as shown in the accompanying drawings. While the present disclosure is described below with reference to particular embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be illustrative only.

FIG. 1 shows a schematic representation of a photodetector that operates as a dynamic photodetector.

FIG. 2A shows a schematic representation in cross-sectional view of a photodetector in accordance with an embodiment of the present disclosure.

FIG. 2B shows a schematic representation in plan view of a photodetector in accordance with an embodiment of the present disclosure.

FIG. 3 shows a graph of photodetector output current as a function of time in accordance with an embodiment of the present disclosure.

FIG. 4A shows a schematic representation in cross-sectional view of a photodetector in accordance with an embodiment of the present disclosure.

FIG. 4B shows a schematic representation in plan view of a photodetector in accordance with an embodiment of the present disclosure.

FIG. 5 shows a schematic representation in cross-sectional view of a photodetector in accordance with an embodiment of the present disclosure.

FIG. 6 shows a schematic representation in cross-sectional view of a photodetector in accordance with an embodiment of the present disclosure.

### DETAILED DESCRIPTION OF EMBODIMENTS

In the following detailed description, for purposes of explanation and not limitation, specific details are set forth in order to provide a better understanding of the present disclosure. It will be apparent to one skilled in the art that the present disclosure may be practiced in other embodiments that depart from these specific details.

To solve the technical problems described above, embodiments described herein provide technical solutions that include highly tunable photodetectors with high dynamic range having a wide variety of applications. For example, in cases where multiple sensors would be used to cover a wide range of possible wavelengths, intensities, or other characteristic of incoming light, multiple controllable voltages may be required to operate all of the sensors. Certain embodiments herein provide photodetectors of the same or greater range while using a single controllable voltage to operate.

Improvements to the sensitivity of photodetectors are also described herein. Embodiments include photodetectors comprising a top layer having a p+ doping concentration separated from a bottom layer having an n+ doping concentration by light absorbing subregions. Sensitivity is improved, at least in part, by one or more of applying a third voltage to the bottom layer when two voltages are applied to the top layer, incorporating a dielectric in the top layer, applying different voltages to a central region and a side region in the top layer, and/or forming a dielectric in the top layer and/or a dielectric in the bottom layer.

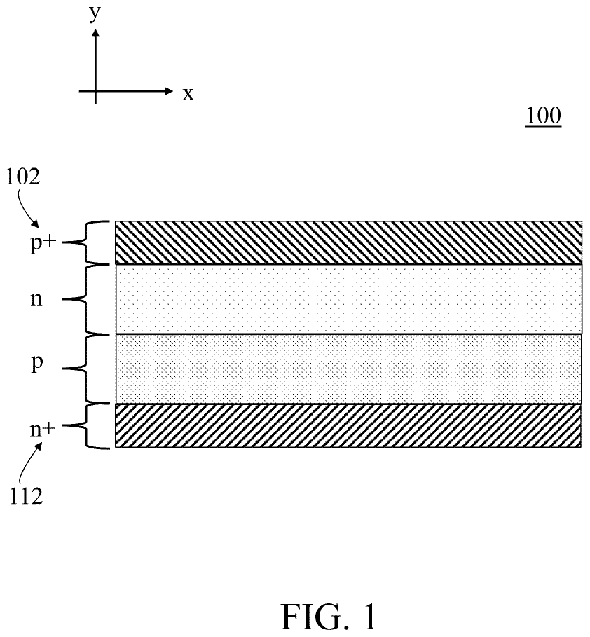

FIG. 1 shows a dynamic photodetector 100. To fabricate the photodetector 100, layers of the photodetector 100 are grown in a direction away from a wafer or a semiconductor-on-insulator (SOI) substrate, beginning with a bottom layer 112 (an n+ layer) and ending with a top layer 102 (a p+ layer) that encounters incident light before the lower layers. The growth direction is orthogonal to the plane of the wafer (i.e., the xz plane, where z is out of the page) in the y-direction beginning with the bottom layer 112 and proceeding epitaxially upward towards the top layer 102.

The photodetector 100 can be operated as follows. The n and p regions of the photodetector 100 act as barriers between the n+ and p+ contact regions. As light arrives on the photodetector 100, photo-generated electrons and holes are trapped in the n region and p region, respectively. This lowers the barriers, which in turn leads to an increase in current between the p+ and n+ contacts, which in turn charges the p and n regions, creating a positive feedback. This feedback happens when a critical number of charges has been absorbed in the material. The number of charges depends on the voltages applied on the contacts of the device and the geometry of the device, but is known in advance. By measuring the time it takes for the device to trigger and knowing the number of charges required to do so, light intensity can be deduced.

Increasing sensitivity is important to many applications of photodetectors. For example, digital cameras that utilize photodetectors would benefit if the photodetectors had increased sensitivity to capture more detail in a scene and/or perform better in low light conditions. In another example, more sensitivity facilitates faster and/or dynamic responses of processes or devices that benefit from obtaining more useable data from incident light in a shorter amount of time. For example, a photodetector that senses ambient light may detect light sooner using the techniques described herein as compared to traditional photodetectors.

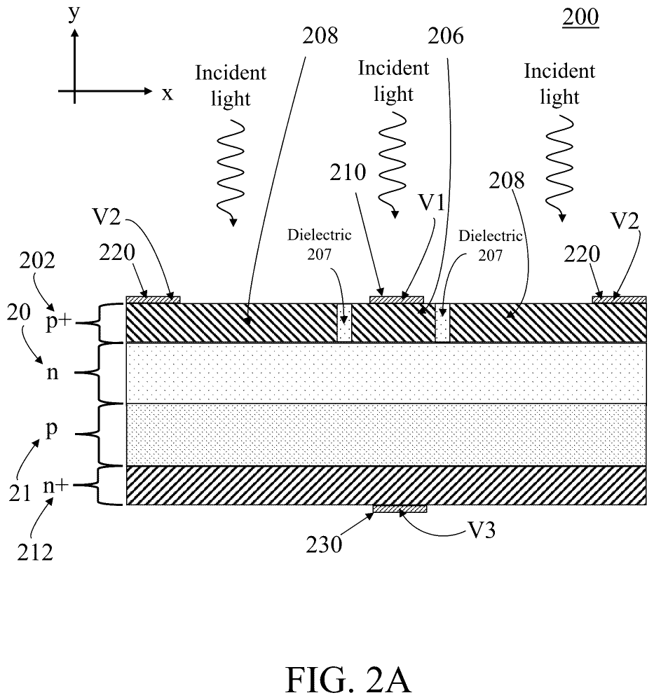

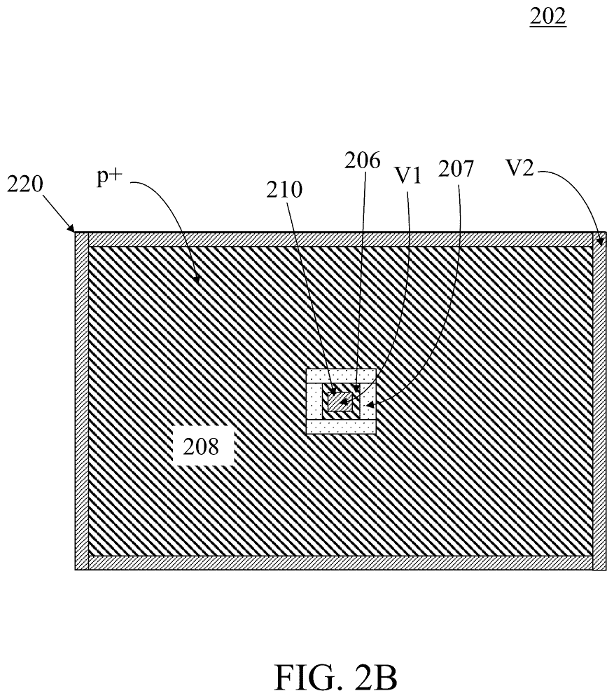

A photodetector that realizes the above-described increase in sensitivity is shown in FIG. 2A. FIG. 2A is a schematic representation in cross-sectional view of a photodetector 200, while FIG. 2B shows a top layer of the photodetector 200 in plan view.

The photodetector 200 includes a top layer 202, which includes a first p+ region 206 (i.e., a central region) coupled to a first contact 210 and surrounded by a dielectric 207. The dielectric 207 separates the central region 206 of the top layer 202 from a second p+ region 208 (i.e., a side region) in the top layer 202 that is coupled to a second contact 220. The first p+ region 206 is electrically isolated from the second p+ region 208 via the dielectric 207. The first contact 210 and the second contact 220 are fabricated on top of the top layer 202. When viewed from above, as shown in FIG. 2B, the second contact 220 may form a contiguous and conductive border or perimeter around the first contact 210. The first contact 210 and the second contact 220 are fabricated above the dielectric 207, at least in this example, where the dielectric 207 forms a contiguous border around the first p+ region 206.

A body region of the photodetector 200 is formed as two subregions of the photodetector 200, namely a light absorbing n-doped semiconductor region 20 and a light absorbing p-doped semiconductor region 21. The light-absorbing n-doped semiconductor region 20 is adjacent to and layered beneath the first p+ region 206, the dielectric 207, and the second p+ region 208 of the top layer 202. The light-absorbing p-doped semiconductor region 21 is adjacent on one of its sides in the x-direction to the n-doped semiconductor region 20 and on another of its sides in the x-direction to a bottom layer 212. The bottom layer 212 is an n+ region coupled to a third contact 230. The two light absorbing regions of the body region have a common interface in the x-direction where they meet. In the y-direction, the overall layer structure of the photodetector 200 has the sequence of: n+pnp+. The light absorbing regions of the photodetector 200 may be made of a suitable semiconductor material such as, for example. silicon or germanium or silicon carbide, or suitable alloy thereof, where the band gap is chosen to be suitable for absorbing incoming photons of a wavelength range to be detected.

An increase in sensitivity may correspond to an increase in photodetector output current. Likewise, a decrease in sensitivity may correspond to a decrease in the photodetector output current. However, changes in sensitivity may not correspond to a change in output current. Changes in sensitivity may correspond to changes in the time it takes for the photodetector to trigger. For example, increasing the sensitivity may correspond to a decrease in triggering time of a dynamic photodetector. An example of operation of a dynamic photodetector is described in the '480 patent. The triggering time of the photodetector is a function of the electric field within the body region of the photodetector, inversely proportional to the light intensity, and tunable via a bias voltage.

To control operation of the photodetector 200, adjust its sensitivity, and/or detect incoming photons from incident light, bias voltages are applied to the contact regions of the photodetector 200. A first voltage V1 is applied to the first contact 210, a second voltage V2 is applied to the second contact 220, and a third voltage is applied to the third contact 230. During a sensing operation (i.e., forward biased), for example, V3 is zero volts, V1 is 1 volt, and V2 can vary from zero volts to 1 volt. If V1 is the same as V2 (i.e., V1=V2), the photodetector 200 operates closer to a sensitivity of a traditional photodetector. In another example, during a reset operation (i.e., reverse biased), a positive voltage V3 (e.g., +3 volts) is applied to the bottom layer 212 and both V1 and V2 can be set to zero volts. In a case where V2 is less than V1 (i.e. V2<V1), photoelectrons generated in the second electrically isolated region 208 are accumulated in the n region 20 near the first p+ region 206 and the output current of the photodetector 200 increases sooner as compared to the case when V2 is the same as V1. Because of this, the photodetector 200 is more sensitive to incident light. In some cases, where V3 is a nonzero voltage, V2 can be set below V3. In an example, V1 is set to zero volts, V3 is set to one volt, and V2 varies up to a value less than V3.

Embodiments of photodetectors may include a central region and a side region in the top and/or bottom layers. Two or more central regions may comprise a larger overall central region of a photodetector. Likewise, two or more side regions may comprise a larger overall side region of a given photodetector. Central regions and side regions described herein may or may not include regions of top or bottom layers that separate a central region from a side region via a dielectric. It is understood that embodiments of photodetectors not described as including dielectrics in their top and/or bottom layers still include central and side regions and may be modified to include dielectrics. To illustrate these types of central regions and side regions, dashed or dotted lines may be used to indicate a general area of a given photodetector. Dashed lines are used, at least in part, because the exact boundary between a central and a side region may depend upon real world conditions such as material composition, doping concentration, structural dimensions, temperature, and so forth. However, in general, a central region includes an area of the respective top layer coupled to a contact for applying V1 and a side region includes an area of the respective top layer coupled to a contact for applying V2, where the central region is adjacent to the side region. Similarly, a central region includes an area of the respective bottom layer coupled to a contact for applying V3 and a side region includes an area of the respective bottom layer coupled to a contact for applying V4 (if present), where the central region is adjacent to the side region.

Each layer of the photodetector 200 may be fabricated according to a particular doping concentration. In at least certain examples, suitable doping levels of the photodetector 200 are 10¹⁹ cm⁻³ for the n+-doped bottom layer 212, 10¹⁴ cm⁻³ for the p-doped semiconductor region 21, 10¹⁴ cm⁻³ for the n-doped semiconductor region 20, and 10¹⁹ cm⁻³ for the p+-doped top layer 202. These example doping levels can be the same across all embodiments. It is understood that other suitable doping concentrations are contemplated herein.

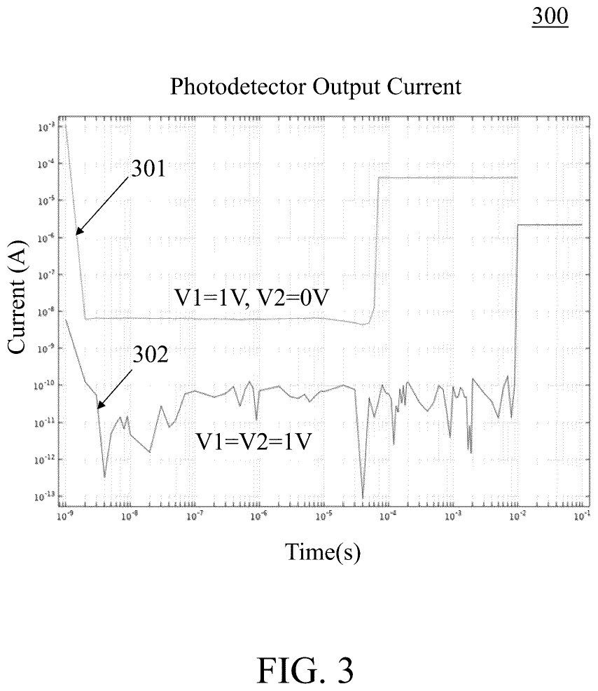

FIG. 3 shows a graph 300 of output current as a function of time for the photodetector 200 in a first simulation 301 where V1 is set to 1 volt and V2 is set to zero volts and a second simulation 302 where V1 and V2 are both set to 1 volt. According to these simulations, for at least some embodiments, the sensitivity of the photodetector 200 can be increased by more than 100 times. Thus, changing V2 from zero volts to one volt while V1 remains fixed at 1 volt correspondingly reduces the sensitivity of the photodetector 200, while changing V2 from one volt to zero volts while V1 remains fixed at 1 volt increases the sensitivity of the photodetector 200.

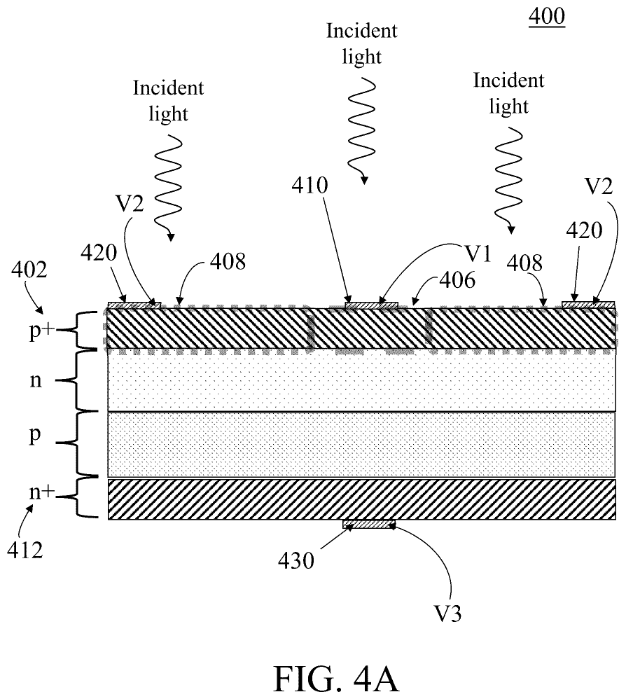

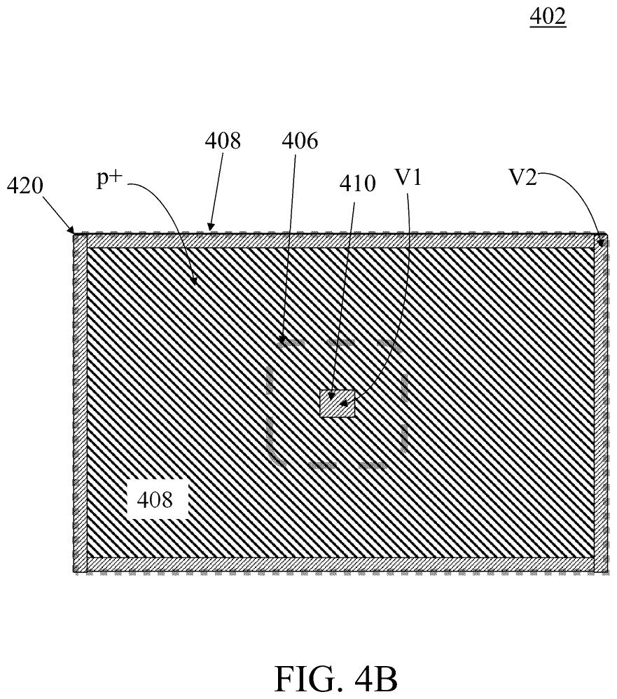

FIGS. 4A and 4B show a photodetector 400 that lacks a dielectric in its top layer yet still achieves the benefits of increased sensitivity described above. A top layer 402 of the photodetector 400 has a p+ doping concentration and includes a first p+ region 406 (i.e., a central region) coupled to a first contact 410, the central region 406 indicated by the longer dashed lines. The top layer 402 also includes a second p+ region 408 (i.e., a side region) coupled to a second contact 420, the side region 408 indicated by the shorter dashed lines. The first contact 410 applies V1 to the central region 406 and a second contact 420 applies V2 to the side region 408. The photodetector 400 includes a bottom layer 412 having a n+ doping concentration that is coupled to a third contact 430 for applying a V3 voltage signal.

Different values of V2 may be applied to the side region 408 via the second contact 420. In at least one example, V2 is any voltage between zero volts up to but excluding 1 volt while V1 remains fixed at 1 volt. However, these regions are at least less electrically isolated (i.e., more conductive there between) as compared to, for example, the first p+ region 206 and the second p+ region 208 shown in FIG. 2A. In this case, some current will flow between the central region 406 and the side region 408, but controlling V2 can still improve sensitivity like in the case of the photodetector 200 shown in FIG. 2A.

The general arrangement of the central region 406 and the side region 408 are shown in FIG. 4B, where the first contact 410 is disposed on top of the central region 406 and the second contact 420 is disposed on top of the side region 408. The central region 406 is shown in FIG. 4B using dashed lines as discussed above, where the side region 408 forms a contiguous region of the top layer 402 that surrounds the central region 406 within the top layer 402.

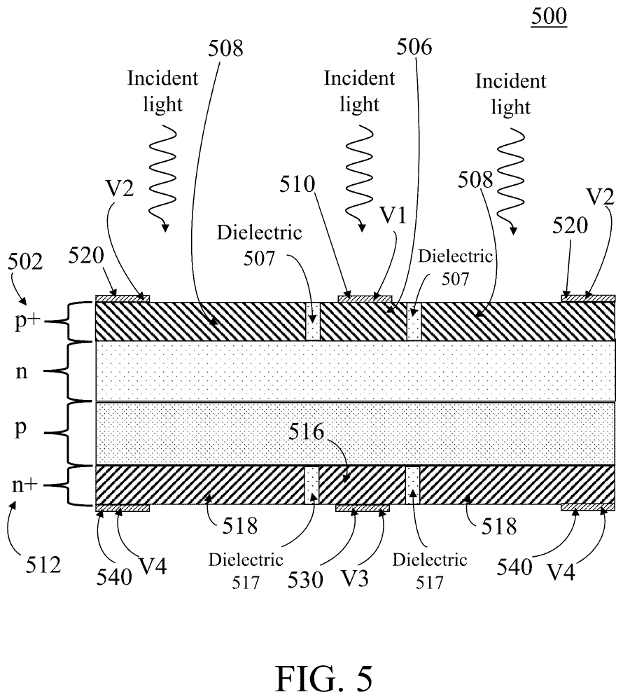

FIG. 5 shows a photodetector 500 that includes a dielectric 507 in a top layer 502 in a similar manner as shown and described above regarding the photodetector 200. The top layer 502 includes a first contact 510 for applying V1 to a first p+ region 506 (i.e., a central region) and a second contact 520 for applying V2 to a second p+ region 508 (i.e., a side region) of the top layer 502. The dielectric 507 is provided in the top layer 502 to thereby electrically isolate the central region 506 from the side region 508 within the top layer 502. The dielectric 507 surrounds the central region 506 within the top layer 502 similarly to that of the dielectric 207 surrounding the first p+ region 206 shown in FIG. 2B.

The photodetector 500 includes a bottom layer 512 where a third contact 530 is coupled to a first n+ region 516 (i.e., a central region) to apply V3 and a fourth contact 540 is coupled to a second n+ region 518 (i.e., a side region) to apply V4. A dielectric 517 is provided in the bottom layer 512 to thereby electrically isolate the central region 516 from the side region 518 within the bottom layer 512.

To adjust sensitivity of the photodetector 500, different values of V2 may be applied to the side region 508 via second contact 520, respectively. Similarly, different values of V4 may may be applied to the side region 518 via second contact 540, respectively, as the photodetector 500 is symmetrical. In the context of sensitivity, a smallest capacitance may set the capacitance of the whole device. So, if V4<V2, then V4 sets the overall capacitance of the photodetector 500. Likewise, if V2<V4, then V2 sets the overall capacitance of the photodetector 500. In certain embodiments, V2 and V4 are adjusted separately to adjust one or more of capacitive effects, positive feedback, and quantum efficiency (QE) of the photodetector 500.

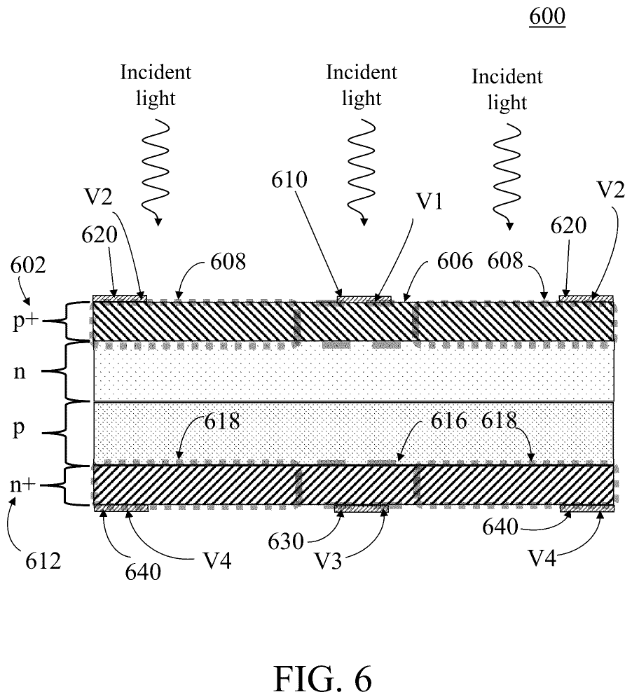

FIG. 6 shows a photodetector 600 that is similar in structure and operation to the photodetector 500, except there is no dielectric in a top layer 602 or a bottom layer 612. The top layer 602 of the photodetector 600 includes a p+ central region 606 and a p+ side region 608. The central region 606 is coupled to a first contact 610 for applying V1 to the central region 606. The side region 608 is coupled to a second contact 620 for applying V2 to the side region 608. As similarly described above in reference to the photodetector 400 shown in FIG. 4A, the top layer 602 of the photodetector 600 still obtains improvements in sensitivity despite the lack of a dielectric in the top layer 602.

The bottom layer 612 of the photodetector 600 includes a n+ central region 616 and a n+ side region 618. The n+ central region 616 is coupled to a third contact 630 for applying V3 to the central region 616. The side region 618 is coupled to a fourth contact 640 for applying V4 to the side region 618. One way in which the photodetector 600 differs from the photodetector 400 is that the fourth contact 640 allows for control of capacitance on the other face of the device (i.e., the face with the top layer 602).

To adjust sensitivity, different values of V2 and/or V4 may be applied to the side regions of photodetector 500 or photodetector 600. While many different examples of particular voltage values may be used with the photodetector 500 or the photodetector 600, one example is that during a sensing operation the four voltages are set to V1=2 volts, V2=1 volt, V3=zero volts, and V4=1 volt.

Similar to as described above regarding the photodetector 400, the central and side regions of the photodetector 600 are not electrically isolated via a dielectric. In this case, some current will flow between the central region 606 and the side region 608 in the top layer 602 and/or between the central region 616 and the side region 618 in the bottom layer 612, but sensitivity improvement can still be obtained.

The present disclosure is neither limited to any single aspect nor embodiment, nor to any combinations and/or permutations of such aspects and/or embodiments. Moreover, each of the aspects of the present disclosure, and/or embodiments thereof, may be employed alone or in combination with one or more of the other aspects and/or embodiments thereof. For the sake of brevity, many of those permutations and combinations will not be discussed and/or illustrated separately herein.

At this point it should be noted that techniques for increasing sensitivity of photodetectors in accordance with the present disclosure as described above may involve the processing of input data and the generation of output data to some extent. This input data processing and output data generation may be implemented in hardware or software. For example, specific electronic components may be employed in one or more processors, a dedicated circuit or similar or related circuitry for implementing the functions associated with determining and/or applying suitable voltage values for the contact(s) in the top and/or bottom layers, measuring a characteristic or quantity from the incident light, automatically adjusting the sensitivity (via the bias voltages) to minimize noise in the electrical signals generated from the incident light encountering a photodetector, and so forth in accordance with the present disclosure as described above. Alternatively, one or more processors operating in accordance with instructions may implement the functions associated with neural networks, controllers, algorithms, or other processes in accordance with the present disclosure as described above. If such is the case, it is within the scope of the present disclosure that such instructions may be stored on one or more non-transitory processor readable storage media (e.g., a magnetic disk, SSD or other storage medium), or transmitted to one or more processors via one or more signals embodied in one or more carrier waves.

The photodetectors thus described herein may be included in systems or devices that have software and/or hardware for operating said photodetectors. For example, a camera system may include one or more lenses for acquiring and focusing ambient light onto a photodetector included in the system, where processing circuitry such as one or more processors executes instructions stored in a memory of the system to dynamically adjust sensitivity of the photodetector by controlling the bias voltages described above. The processing circuitry may receive as an input a target sensitivity value from a user and set the voltages of the photodetector appropriately based on the instructions (e.g., the user using an input device of the camera to set the sensitivity to a particular amount). In another example, the photodetector may be used in fiberoptic communications to gain more information/data from the encoded light signals passing through a fiber optic network.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of at least one particular implementation in at least one particular environment for at least one particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A photodetector device comprising:
a top layer comprising a central region and a side region each composed of a first type of doped semiconductor material, the central region coupled to a first contact to receive a first voltage, the side region coupled to a second contact to receive a second voltage;
a first light absorbing region composed of a second type of doped semiconductor material;
a second light absorbing region composed of a third type of doped semiconductor material; and
a bottom layer composed of a fourth type of doped semiconductor material and coupled to a third contact to receive a third voltage;
wherein the first light absorbing region has a lower doping concentration than the bottom layer, and wherein the second light absorbing region has a lower doping concentration than the top layer.

2. The device of claim 1, further comprising a fourth contact coupled to the bottom layer to receive a fourth voltage.

3. The photodetector device of claim 1, wherein the top layer comprises a dielectric formed between the central region of the top layer and the side region of the top layer.

4. The photodetector device of claim 3, wherein the bottom layer comprises:
a central region coupled to the third contact; and
a side region coupled to a fourth contact to receive a fourth voltage;
wherein the bottom layer is disposed adjacent the second light absorbing region.

5. The photodetector device of claim 4, wherein the bottom layer further comprises a dielectric formed between the central region of the bottom layer and the side region of the bottom layer.

6. The photodetector device of claim 1, wherein the photodetector device operates at a first sensitivity responsive to the first voltage and the second voltage being the same and operates at a second sensitivity responsive to the second voltage being less than the first voltage, and wherein the second sensitivity is higher than the first sensitivity.

7. The photodetector device of claim 6, wherein the second sensitivity increases as the second voltage decreases while the first voltage and the third voltage remain fixed.

8. The photodetector device of claim 6, wherein the photodetector device operates at the first sensitivity responsive to:
setting the first voltage to 1 volt, the second voltage to 1 volt, and the third voltage to zero volts, wherein the photodetector device changes the second sensitivity by setting the second voltage to be less than the first voltage; or
setting the third voltage to a nonzero voltage, wherein the photodetector device changes the second sensitivity by setting the second voltage to be less than the third voltage.

9. The photodetector device of claim 1, wherein the first type of doped semiconductor material and the third type of doped semiconductor material are both p-type doped semiconductor material, and wherein the second type of doped semiconductor material and the fourth type of doped semiconductor material are both n-type doped semiconductor material.

10. The photodetector device of claim 1, wherein the first type of doped semiconductor material and the third type of doped semiconductor material are both n-type doped semiconductor material, and wherein the second type of doped semiconductor material and the fourth type of doped semiconductor material are both p-type doped semiconductor material.

11. A method of increasing a sensitivity of a photodetector device, the method comprising:
providing the photodetector device with:
a top layer comprising a central region and a side region each composed of a first type of doped semiconductor material, the central region coupled to a first contact to receive a first voltage, the side region coupled to a second contact to receive a second voltage;
a first light absorbing region composed of a second type of doped semiconductor material;
a second light absorbing region composed of a third type of doped semiconductor material; and
a bottom layer composed of a fourth type of doped semiconductor material and coupled to a third contact to receive a third voltage;
wherein the first light absorbing region has a lower doping concentration than the bottom layer, and wherein the second light absorbing region has a lower doping concentration than the top layer; and
increasing the sensitivity of the photodetector device by:
setting the first contact to the first voltage;
setting the third contact to the third voltage; and
setting the second voltage to be less than the first voltage while the second voltage and the third voltage remain fixed.

12. The method of claim 11, wherein providing the photodetector with the bottom layer comprises the bottom layer coupled to a fourth contact to receive a fourth voltage, and wherein increasing the sensitivity of the photodetector device comprises setting the fourth contact to the fourth voltage.

13. The method of claim 11, wherein providing the photodetector with the top layer comprises the top layer comprising a dielectric formed between the central region of the top layer and the side region of the top layer.

14. The method of claim 13, wherein providing the photodetector with the bottom layer comprises the bottom layer comprising a central region coupled to the third contact and a side region coupled to a fourth contact to receive a fourth voltage, and wherein the bottom layer is disposed adjacent the second light absorbing region.

15. The method of claim 14, wherein providing the photodetector with the bottom layer further comprises the bottom layer comprising a dielectric formed between the central region of the bottom layer and the side region of the bottom layer.

16. The method of claim 1, wherein increasing the sensitivity of the photodetector device further comprises:
operating the photodetector device at a first sensitivity by setting the first voltage and the second voltage to be the same; and
operating the photodetector device at a second sensitivity by setting the second voltage to be less than the first voltage, wherein the second sensitivity is higher than the first sensitivity.

17. The method of claim 16, wherein the second sensitivity increases as the second voltage decreases while the first voltage and the third voltage remain fixed.

18. The method of claim 11, wherein the first type of doped semiconductor material and the third type of doped semiconductor material are both p-type doped semiconductor material, and wherein the second type of doped semiconductor material and the fourth type of doped semiconductor material are both n-type doped semiconductor material.

19. The method of claim 11, wherein the first type of doped semiconductor material and the third type of doped semiconductor material are both n-type doped semiconductor material, and wherein the second type of doped semiconductor material and the fourth type of doped semiconductor material are both p-type doped semiconductor material.

20. A method of manufacturing a photodetector device, the method comprising:
fabricating a top layer comprising a central region and a side region each composed of a first type of doped semiconductor material, the central region coupled to a first contact to receive a first voltage, the side region coupled to a second contact to receive a second voltage;
fabricating a first light absorbing region composed of a second type of doped semiconductor material;
fabricating a second light absorbing region composed of a third type of doped semiconductor material; and
fabricating a bottom layer composed of fourth type of doped semiconductor material and coupled to a third contact to receive a third voltage;
wherein the first light absorbing region has a lower doping concentration than the bottom layer, and wherein the second light absorbing region has a lower doping concentration than the top layer.

21. The method of claim 20, wherein fabricating the bottom layer comprises the bottom layer coupled to a fourth contact to receive a fourth voltage.

22. The method of claim 20, wherein fabricating the top layer comprises fabricating a dielectric between the central region of the top layer and the side region of the top layer.

23. The method of claim 22, wherein fabricating the bottom layer comprises:
fabricating a central region in the bottom layer coupled to the third contact; and
fabricating a side region in the bottom layer coupled to a fourth contact to receive a fourth voltage;
wherein the bottom layer is disposed adjacent the second light absorbing region.

24. The method of claim 23, wherein fabricating the bottom layer further comprises:
forming a dielectric between the central region of the bottom layer and the side region of the bottom layer.

25. The method of claim 20, wherein the first type of doped semiconductor material and the third type of doped semiconductor material are both p-type doped semiconductor material, and wherein the second type of doped semiconductor material and the fourth type of doped semiconductor material are both n-type doped semiconductor material.

26. The method of claim 20, wherein the first type of doped semiconductor material and the third type of doped semiconductor material are both n-type doped semiconductor material, and wherein the second type of doped semiconductor material and the fourth type of doped semiconductor material are both p-type doped semiconductor material.
